(19) United States
(12) Patent Application Publication
(10) Pub. No.: US 2026/0082853 A1
(43) Pub. Date: Mar. 19, 2026

(54) WAFER DETECTION UNIT

(71) Applicant: Mitsubishi Electric Corporation, Tokyo (JP)

(72) Inventor: Kazuki NAKAMURA, Fukuoka (JP)

(73) Assignee: Mitsubishi Electric Corporation, Tokyo (JP)

(21) Appl. No.: 19/245,233

(22) Filed: Jun. 20, 2025

(30) Foreign Application Priority Data
Sep. 18, 2024 (JP) 2024-160736

(51) Int. Cl. H01L 21/67; H01L 21/68

(52) U.S. Cl. CPC H10P 72/0606; H10P 72/53

(57) ABSTRACT

A wafer detection unit includes: support pins that can support a semiconductor wafer; a resin part disposed at an end of each of the support pins, the resin part including a through hole; a light-emitting optical fiber disposed in a periphery of each of the support pins and inside the resin part, the light-emitting optical fiber having one end being exposed from a side in which the through holes of the resin parts face the semiconductor wafer; a light-receiving optical fiber disposed in a center portion of each of the support pins, the light-receiving optical fiber having one end facing a corresponding one of the through holes of the resin parts; a light-receiving sensor connected to an other end of each of the light-receiving optical fibers; and a controller that determines a presence or absence of the semiconductor wafer, based on a detection signal obtained from the light-receiving sensor.

### BACKGROUND

### Technical Field

The present disclosure relates to a wafer detection unit.

### Description of the Background Art

Conventionally, semiconductor wafers have been detected by placing the semiconductor wafers each on a reflective or transparent optical sensor disposed on a wafer stage base and reflecting or blocking incident light from the optical sensor (see, for example, WO2006/104121).

According to the technology described in WO2006/104121, the reflective optical sensor disposed on the wafer stage base applies the incident light to the semiconductor wafer, and receives the reflected light to determine the presence or absence of the semiconductor wafer.

According to the technology described in WO2006/104121, however, the reflective optical sensor is disposed above the semiconductor wafer. When an oxide film or an organic film is deposited on the semiconductor wafer, the oxide film or the organic film acts to attenuate or scatter the reflected light from the semiconductor wafer. Thus, the technology has a problem in that the detection accuracy on the presence or absence of the semiconductor wafer depends on a deposition state of the semiconductor wafer.

### SUMMARY

The present disclosure has an object of providing a technology enabling detection of the presence or absence of a semiconductor wafer, without depending on a deposition state of the semiconductor wafer.

A wafer detection unit according to the present disclosure includes a base, a plurality of support pins, resin parts, light-emitting optical fibers, a light source, light-receiving optical fibers, a light-receiving sensor, and a controller. The plurality of support pins are erect on the base and can support at least one semiconductor wafer. The resin part is disposed at an end of each of the support pins such that the resin part can be in contact with the semiconductor wafer, the resin part including a through hole in a center portion. The light-emitting optical fiber disposed in a periphery of each of the support pins and inside the resin part, the light-emitting optical fiber having one end being exposed from a side in which the through holes of the resin parts face the semiconductor wafer. The light source is connected to an other end of each of the light-emitting optical fibers. The light-receiving optical fiber is disposed in a center portion of each of the support pins, the light-receiving optical fiber having one end facing a corresponding one of the through holes of the resin parts. The light-receiving sensor is connected to an other end of each of the light-receiving optical fibers. The controller determines a presence or absence of the semiconductor wafer, based on a detection signal obtained from the light-receiving sensor. When the semiconductor wafer is placed on the plurality of support pins through the resin parts, outgoing light emitted from the light source is emitted from the light-emitting optical fibers toward the semiconductor wafer, and the outgoing light is reflected from the semiconductor wafer. The reflected light from the semiconductor wafer is transmitted from the through holes of the resin parts to the light-receiving sensor through the light-receiving optical fibers. The controller determines the presence of the semiconductor wafer when obtaining the detection signal from the light-receiving sensor, and determines the absence of the semiconductor wafer when the controller does not obtain the detection signal.

Thus, the presence or absence of the semiconductor wafer can be detected without depending on a deposition state of the semiconductor wafer.

These and other objects, features, aspects, and advantages of the present disclosure will become more apparent from the following detailed description of the present disclosure when taken in conjunction with the accompanying drawings.

### BRIEF DESCRIPTION OF THE DRAWINGS

FIG. 1 is a top view of a wafer detection unit according to Embodiment 1;

FIG. 2 is a cross-sectional view of the wafer detection unit according to Embodiment 1;

FIG. 3 is a top view of a support pin included in the wafer detection unit according to Embodiment 1;

FIG. 4 is a top view of a support pin included in a wafer detection unit according to Modification 1 of Embodiment 1;

FIG. 5 is a top view of a support pin included in a wafer detection unit according to Modification 2 of Embodiment 1;

FIG. 6 is a cross-sectional view of the support pin in the absence of the semiconductor wafer in Embodiment 1;

FIG. 7 is a cross-sectional view of the support pin in the presence of the semiconductor wafer in Embodiment 1;

FIG. 8 is a cross-sectional view of the wafer detection unit when the semiconductor wafer is placed in a slanting position in Embodiment 1;

FIG. 9 is a cross-sectional view of the wafer detection unit when a warped semiconductor wafer is placed in Embodiment 1;

FIG. 10 is a cross-sectional view of the support pin in the absence of a semiconductor wafer in Embodiment 2;

FIG. 11 is a cross-sectional view of a support pin in the presence of the semiconductor wafer in Embodiment 2;

FIG. 12 is a top view of the support pin included in a wafer detection unit according to Embodiment 2;

FIG. 13 is a top view of a wafer detection unit according to Embodiment 3;

FIG. 14 is a cross-sectional view where a semiconductor wafer whose φ=6 is placed on the wafer detection unit according to Embodiment 3;

FIG. 15 is a cross-sectional view where a semiconductor wafer whose φ=12 is placed on the wafer detection unit according to Embodiment 3;

FIG. 16 is a top view where semiconductor wafers with different diameters are placed on the wafer detection unit according to Embodiment 3; and

FIG. 17 is a cross-sectional view of the wafer detection unit on which a semiconductor wafer with a flatness defect is placed in Embodiment 3.

### DESCRIPTION OF THE PREFERRED EMBODIMENTS

### Embodiment 1

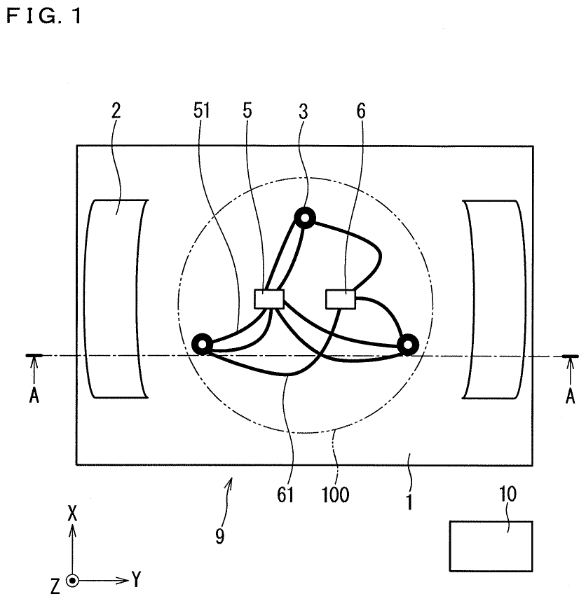

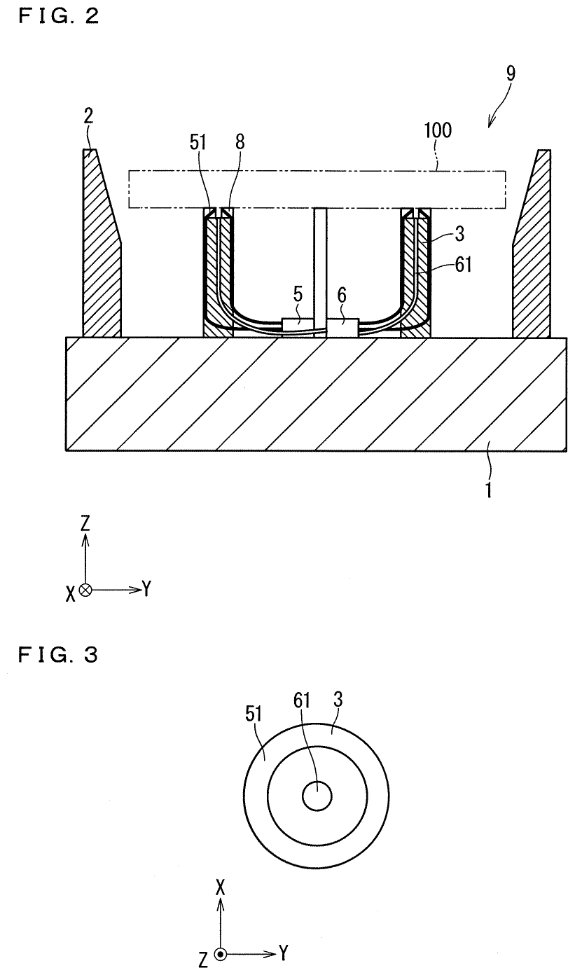

Embodiment 1 will be described below with reference to the drawings. FIG. 1 is a top view of a wafer detection unit 9 according to Embodiment 1. FIG. 2 is a cross-sectional view of the wafer detection unit 9 according to Embodiment 1, specifically, a cross section taken along the line A-A of FIG. 1.

In FIG. 1, X direction, Y direction, and Z direction are orthogonal to one another. In the subsequent diagrams, X direction, Y direction, and Z direction are also orthogonal to one another. In the following description, a direction including X direction and −X direction that is a direction opposite to X direction will be referred to as an X-axis direction. In the following description, a direction including Y direction and −Y direction that is a direction opposite to Y direction will be referred to as a Y-axis direction. In the following description, a direction including Z direction and −Z direction that is a direction opposite to Z direction will be referred to as a Z-axis direction.

As illustrated in FIGS. 1 and 2, the wafer detection unit 9 includes a base 1, a pair of catch pans 2, a plurality of support pins 3, resin parts 8, light-emitting optical fibers 51, a light source 5, light-receiving optical fibers 61, a light-receiving sensor 6, and a controller 10.

The base 1 is formed into a quadrangular shape in a top view (when viewed in Z direction). The pair of catch pans 2 is erect to face both ends of the base 1 in the Y-axis direction (Z direction). The inner circumferential side of the pair of catch pans 2 is tapered. Dropping a semiconductor wafer 100 aligns the semiconductor wafer 100.

Each of the support pins 3 is formed into, for example, a cylindrical column with a material containing a metal, and is erect in a region between the pair of catch pans 2 on the base 1. Thus, the support pins 3 can support the semiconductor wafer 100. Specifically, the support pins 3 can support the lower surface of the semiconductor wafer 100 (a surface in −Z direction). The support pins 3 are disposed at positions where the semiconductor wafer 100 can be held. The semiconductor wafer 100 is automatically transported by robot arms that are not illustrated. Although the three support pins 3 are disposed at the positions facing a periphery of the semiconductor wafer 100 in FIG. 1, three or more support pins 3 can be disposed within the bounds of not interfering with operations of the robot arms.

The resin part 8 is formed into a cylindrical column, and is disposed at the end of each of the support pins 3 such that the resin part 8 can be in contact with the lower surface of the semiconductor wafer 100.

The light-emitting optical fiber 51 extends from the light source 5 to the upper end (an end in Z direction) of the resin part 8 through the support pin 3. The light-receiving optical fiber 61 extends from the light-receiving sensor 6 to the upper end of the support pin 3 through the support pin 3.

The controller 10 includes a processor (not illustrated) such as a central processing unit (CPU). The controller 10 is connected to the light-receiving sensor 6, and determines the presence or absence of the semiconductor wafer 100, based on a detection signal obtained from the light-receiving sensor 6. Here, the controller 10 may store, in a memory included in the controller 10, a table including intensity data on reflected light which differs for each material of a substrate included in the semiconductor wafer 100. The controller 10 determines a type of the semiconductor wafer 100 based on the table. Although the controller 10 is not connected to the light-receiving sensor 6 in FIG. 1, the controller 10 is actually connected to the light-receiving sensor 6.

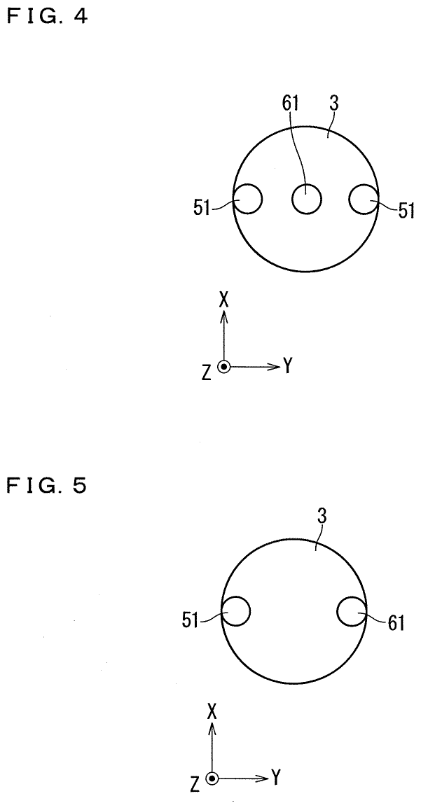

Next, a structure of the support pin 3 and the resin part 8 will be described. FIG. 3 is a top view of the support pin 3 included in the wafer detection unit 9 according to Embodiment 1. FIG. 4 is a top view of the support pin 3 included in the wafer detection unit 9 according to Modification 1 of Embodiment 1. FIG. 5 is a top view of the support pin 3 included in the wafer detection unit 9 according to Modification 2 of Embodiment 1.

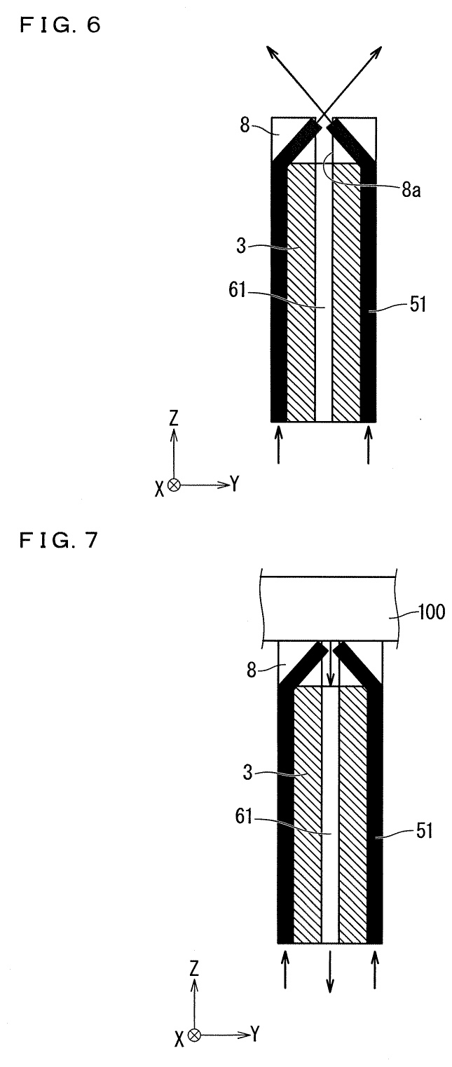

As illustrated in FIGS. 2 and 3, the light-emitting optical fiber 51 is disposed in a periphery of the support pin 3 and inside the resin part 8. One end of the light-emitting optical fiber 51 is exposed from a side in which a through hole 8a (see FIG. 6) of the resin part 8 faces the semiconductor wafer 100 (in Z direction). Furthermore, the other end of the light-emitting optical fiber 51 is connected to the light source 5. The light-emitting optical fiber 51 is disposed along the entirety of the periphery of the support pin 3. The amount of light emitted from the light-emitting optical fiber 51 with this structure can be increased.

As illustrated in FIG. 4, two holes (not illustrated) may be formed in positions facing each other in the periphery of the support pin 3, and two light-emitting optical fibers 51 may be disposed in the respective two holes. Even when one of the light-emitting optical fibers 51 has a malfunction, light can be emitted only by the other light-emitting optical fiber 51.

As illustrated in FIGS. 3 and 4, the light-receiving optical fiber 61 is disposed in a center portion of the support pin 3. One end of the light-receiving optical fiber 61 faces the through hole 8a (see FIG. 6) of the resin part 8. Furthermore, the other end of the light-receiving optical fiber 61 is connected to the light-receiving sensor 6 (see FIG. 2).

Here, when the light-emitting optical fiber 51 is disposed in the resin part 8, a hole, for example, angled in a range of 40 to 60° in Y direction, preferably, a hole angled at 45° is formed in the resin part 8 so that the light emitted from the light-emitting optical fiber 51 reaches the semiconductor wafer 100 and the light reflected from the semiconductor wafer 100 is incident on the light-receiving optical fiber 61. Then, one end of the light-emitting optical fiber 51 is disposed at the end of the resin part 8.

The light-receiving optical fiber 61 is not disposed in the resin part 8, and the through hole 8a (see FIG. 6) penetrating the upper surface (a surface in Z direction) and the lower surface (a surface in-Z direction) is formed. The through hole 8a is formed in a range within which the light emitted from the light-emitting optical fiber 51 is reflected from the semiconductor wafer 100 and the reflected light is incident on the light-receiving optical fiber 61. For example, the through hole 8a is formed in the center portion of the resin part 8. This structure enables the light emitted from the light-emitting optical fiber 51 to be reflected from the semiconductor wafer 100 and be directly incident on the light-receiving optical fiber 61 by passing through the through hole 8a, without through the body of the resin part 8. When the light is incident on the light-emitting optical fiber 51 through the body of the resin part 8, the intensity of light decreases, and the detection sensitivity decreases. Thus, the light is preferably directly made incident on the light-receiving optical fiber 61. The body of the resin part 8 is a portion of the resin part 8 except the through hole 8a.

As illustrated in FIG. 5, the light-emitting optical fiber 51 and the light-receiving optical fiber 61 may be disposed at positions facing each other in the periphery of the support pin 3 and the resin part 8 (see FIG. 6). Specifically, one end of the light-emitting optical fiber 51 is exposed from the through hole 8a (see FIG. 6) of the resin part 8 which faces the semiconductor wafer 100. One end of the light-receiving optical fiber 61 is exposed from a portion facing the light-emitting optical fiber 51 on the side where the through hole 8a of the resin part 8 faces the semiconductor wafer 100. Specifically, the structure of FIG. 5 is obtained by replacing the light-receiving optical fiber 61 disposed in the center portion of the support pin 3 with one of positions of the right and left light-emitting optical fibers 51 in FIG. 6 that will be described later.

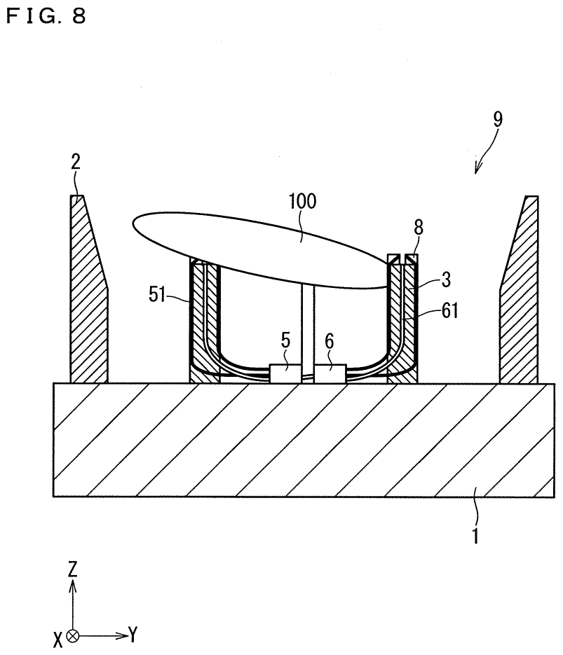

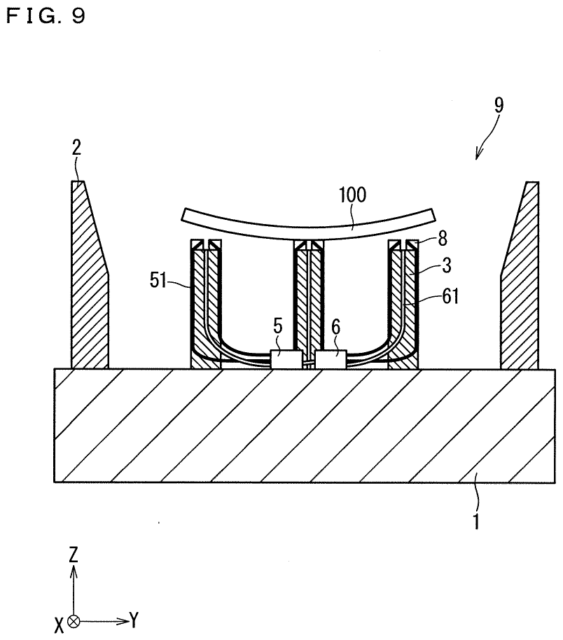

Next, operations of the wafer detection unit 9 will be described. Here, the operations of the wafer detection unit 9 having a structure of the support pin 3 and the resin part 8 in FIG. 3 or 4 will be described. FIG. 6 is a cross-sectional view of the support pin 3 in the absence of the semiconductor wafer 100 in Embodiment 1. FIG. 7 is a cross-sectional view of the support pin 3 in the presence of the semiconductor wafer 100 in Embodiment 1. FIG. 8 is a cross-sectional view of the wafer detection unit 9 when the semiconductor wafer 100 is placed in a slanting position in Embodiment 1. FIG. 9 is a cross-sectional view of the wafer detection unit 9 when the warped semiconductor wafer 100 is placed in Embodiment 1.

As illustrated in FIG. 6, the light incident from the light source 5 is emitted, through the light-emitting optical fiber 51, from the end of the resin part 8 disposed at the end of the support pin 3. Since the semiconductor wafer 100 is not placed, the incident light is not reflected. Thus, no light is incident on the light-receiving optical fiber 61 connected to the light-receiving sensor 6. Consequently, no light is delivered to the light-receiving sensor 6. When no light is delivered to the light-receiving sensor 6 from any one of the light-receiving optical fibers 61 included in all the support pins 3, the light-receiving sensor 6 does not output a detection signal. In other words, when no light is delivered to the light-receiving sensor 6 from any of the light-receiving optical fibers 61 included in all the support pins 3, the light-receiving sensor 6 does not output a detection signal. When the controller 10 (see FIG. 1) does not obtain the detection signal from the light-receiving sensor 6, the controller 10 determines the absence of the semiconductor wafer 100.

As illustrated in FIG. 7, the light incident from the light source 5 is emitted, through the light-emitting optical fiber 51, from the end of the resin part 8 disposed at the end of the support pin 3. Since the semiconductor wafer 100 is placed, the light reflected from the semiconductor wafer 100 is delivered to the light-receiving sensor 6 through the light-receiving optical fiber 61 in the support pin 3. When light is delivered to the light-receiving sensor 6 from all the light-receiving optical fibers 61 included in all the support pins 3, the light-receiving sensor 6 outputs a detection signal. When obtaining the detection signal from the light-receiving sensor 6, the controller 10 (see FIG. 1) determines the presence of the semiconductor wafer 100.

As illustrated in FIG. 8, when the semiconductor wafer 100 is placed in a slanting position due to a transport mistake, no reflected light is delivered from the support pin 3 immediately above which the semiconductor wafer 100 is not placed. As such, determining a failure in emission of the reflected light from all of the support pins 3 to be a transport error can suppress damaging automatic carrier arms (not illustrated) and the semiconductor wafer 100. Similarly, misalignment of the semiconductor wafer 100 can also be determined to be a transport error.

Furthermore, when an additional support pin 3 is disposed at a position corresponding to the center portion of the semiconductor wafer 100 as illustrated in FIG. 9, the semiconductor wafer 100 that is significantly warped can be detected. For example, when the semiconductor wafer 100 that is significantly warped into a concave shape is placed, the center portion of the semiconductor wafer 100 is in contact with the support pin 3, and the periphery of the semiconductor wafer 100 is not in contact with the support pin 3. Thus, although reflected light is delivered from the support pin 3 disposed at the position corresponding to the center portion of the semiconductor wafer 100, no reflected light is delivered from the support pin 3 disposed at the position corresponding to the periphery of the semiconductor wafer 100. Determining a failure in delivery of reflected light from any of the support pins 3 to be a warpage of the semiconductor wafer 100 similarly to a transport error enables removal of the semiconductor wafer 100 that is significantly warped, before performing processes on the semiconductor wafer 100.

The wafer detection unit 9 according to Embodiment 1 includes: the base 1; the support pins 3 that are erect on the base 1 and can support the semiconductor wafer 100; the resin part 8 disposed at an end of each of the support pins 3 such that the resin part 8 can be in contact with the semiconductor wafer 100, the resin part 8 including the through hole 8a in a center portion; the light-emitting optical fiber 51 disposed in a periphery of each of the support pins 3 and inside the resin part 8, the light-emitting optical fiber 51 having one end being exposed from a side in which the through holes 8a of the resin parts 8 face the semiconductor wafer 100; the light source 5 connected to an other end of each of the light-emitting optical fibers 51; the light-receiving optical fiber 61 disposed in a center portion of each of the support pins 3, the light-receiving optical fiber 61 having one end facing a corresponding one of the through holes 8a of the resin parts 8; the light-receiving sensor 6 connected to an other end of each of the light-receiving optical fibers 61; and the controller 10 that determines a presence or absence of the semiconductor wafer 100, based on a detection signal obtained from the light-receiving sensor 6. When the semiconductor wafer 100 is placed on the support pins 3 through the resin parts 8, outgoing light emitted from the light source 5 is emitted from the light-emitting optical fibers 51 toward the semiconductor wafer 100, the outgoing light is reflected from the semiconductor wafer 100, and the reflected light from the semiconductor wafer 100 is transmitted from the through holes 8a of the resin parts 8 to the light-receiving sensor 6 through the light-receiving optical fibers 61. The controller 10 determines the presence of the semiconductor wafer 100 when obtaining the detection signal from the light-receiving sensor 6, and determines the absence of the semiconductor wafer 100 when the controller 10 does not obtain the detection signal.

Such a structure in Embodiment 1 significantly shortens a distance between the light-emitting optical fiber 51 and the semiconductor wafer 100 and a distance between the semiconductor wafer 100 and the light-receiving optical fiber 61. Thus, light is incident on and is received by the semiconductor wafer 100 at a very short distance. Shortening a distance on incidence and reception of light can suppress attenuation and scattering of the light upon incidence.

Thus, the presence or absence of the semiconductor wafer 100 can be detected without depending on a deposition state of the semiconductor wafer 100.

Furthermore, shortening a distance between the semiconductor wafer 100 and the light-receiving optical fiber 61 enables reception of little reflected light, and does not reduce the detection accuracy even when the reflected light from the semiconductor wafer 100 on which a film has been deposited is attenuated or scattered. Thus, a decrease in the detection accuracy of polycrystalline wafers whose reflected light is expected to be significantly attenuated or scattered can be suppressed.

The plurality of support pins 3 include at least three support pins 3 disposed at positions corresponding to the periphery of the semiconductor wafer 100. Thus, a failure in emission of the reflected light from all of the support pins 3 can be determined to be a transport error, assuming that the semiconductor wafer 100 is placed in a slanting position or is misaligned.

The plurality of support pins 3 further include one support pin 3 disposed at a position corresponding to the center portion of the semiconductor wafer 100. When the semiconductor wafer 100 that is significantly warped into a concave shape is placed, reflected light is delivered from the support pin 3 disposed at the position corresponding to the center portion of the semiconductor wafer 100. No reflected light is, however, delivered from the support pin 3 disposed at a position corresponding to the periphery of the semiconductor wafer 100. Determining a failure in delivery of reflected light from any of the support pins 3 to be a warpage of the semiconductor wafer 100 similarly to a transport error enables removal of the semiconductor wafer 100 that is significantly warped, before performing processes on the semiconductor wafer 100.

Here, the controller 10 includes a table including intensity data on reflected light which differs for each material of substrates included in the semiconductor wafers 100. For example, reflected light from a SiC wafer is significantly attenuated or scattered, whereas reflected light from a Si wafer is remarkable. Thus, the controller 10 including a table including intensity data on reflected light of both wafers can determine a type of each of the semiconductor wafers 100, based on the table.

Furthermore, integration of the support pin 3, the light-emitting optical fiber 51, and the light-receiving optical fiber 61 can ensure space in which the automatic carrier arms can be moved up and down vertically (Z-axis direction) with respect to the position of the semiconductor wafer 100, and does not interfere with transporting the semiconductor wafer 100 by the arms.

Furthermore, since the light-emitting optical fiber 51 and the light-receiving optical fiber 61 are disposed in the support pin 3 that holds the semiconductor wafer 100, components for attaching the light-emitting optical fiber 51 and the light-receiving optical fiber 61 need not be newly provided. This can suppress an increase in the number of components of the wafer detection unit 9.

Furthermore, disposing the resin part 8 at the end of the support pin 3 enables its replacement when the resin part 8 is damaged.

Since not only the light-emitting optical fiber 51 but also the light-receiving optical fiber 61 is disposed in the periphery of the support pin 3 according to Modification 2 of Embodiment 1, the structure of the support pin 3 is simplified. This facilitates maintenance work including replacement of the resin part 8, the light-emitting optical fiber 51, or the light-receiving optical fiber 61.

### Embodiment 2

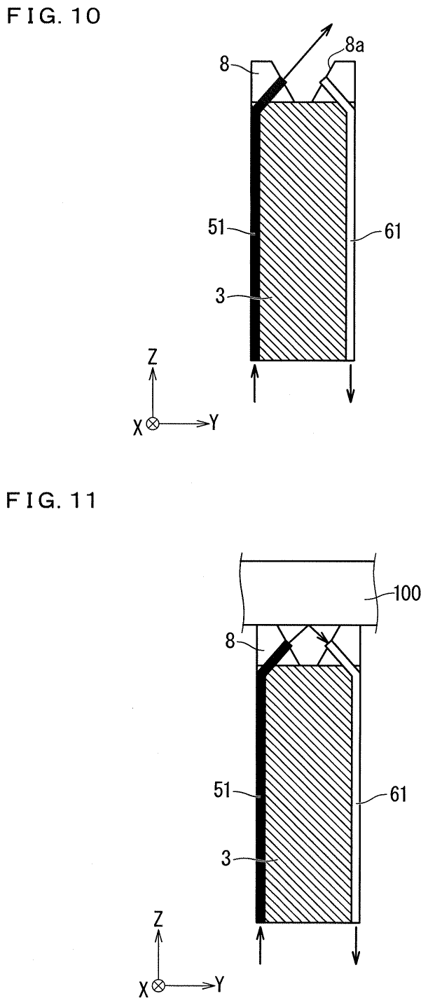

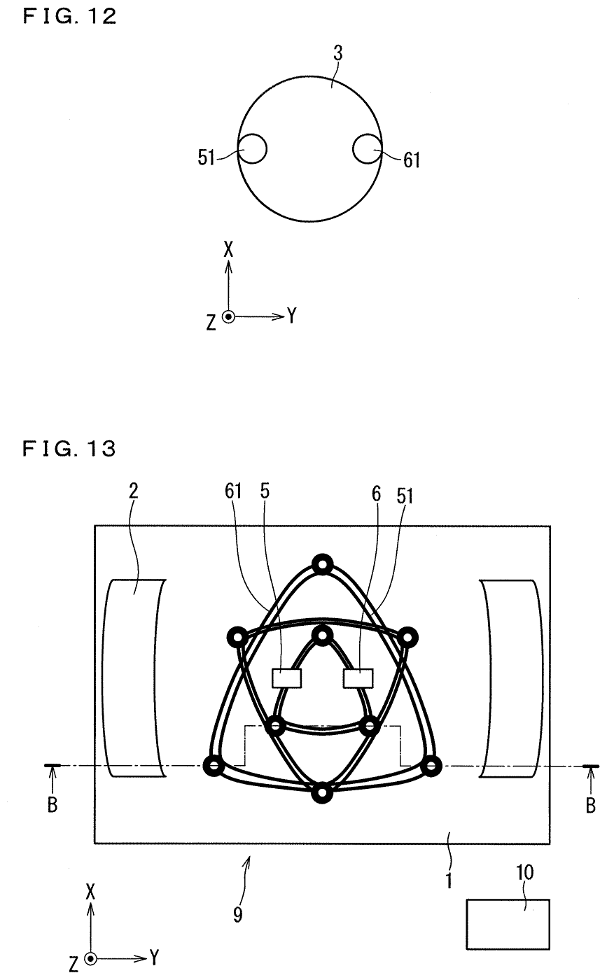

Next, Embodiment 2 will be described. FIG. 10 is a cross-sectional view of the support pin 3 in the absence of the semiconductor wafer 100 in Embodiment 2. FIG. 11 is a cross-sectional view of the support pin 3 in the presence of the semiconductor wafer 100 in Embodiment 2. FIG. 12 is a top view of the support pin 3 included in the wafer detection unit 9 according to Embodiment 2. In Embodiment 2, the same reference numerals are assigned to the same constituent elements described in Embodiment 1, and the description thereof will be omitted.

As illustrated in FIGS. 10 to 12, the shape of the through hole 8a of the resin part 8 according to Embodiment 2 differs from that of Embodiment 1. Furthermore, the arrangement of the light-emitting optical fiber 51 and the light-receiving optical fiber 61 also differs from that of Embodiment 1.

The resin part 8 is disposed at the end of each of the support pins 3 so that the resin part 8 can be in contact with the semiconductor wafer 100, and includes, in a center portion of the resin part 8, the through hole 8a that has an inverted conical shape whose diameter is increased from the support pin 3 toward the semiconductor wafer 100.

The light-emitting optical fiber 51 is disposed in the periphery of each of the support pins 3 and inside the resin part 8. One end of the light-emitting optical fiber 51 is exposed from a sloping surface forming the inverted conical through hole 8a of the resin part 8.

The light-receiving optical fiber 61 is disposed in the periphery of each of the support pins 3 and inside the resin part 8. One end of the light-receiving optical fiber 61 is exposed from a portion facing the light-emitting optical fiber 51 in the sloping surface forming the inverted conical through hole 8a of the resin part 8. In other words, the one end of the light-receiving optical fiber 61 faces the one end of the light-emitting optical fiber 51.

Next, operations of the wafer detection unit 9 will be described. As illustrated in FIG. 10, the light incident from the light source 5 (see FIG. 2) is emitted, through the light-emitting optical fiber 51, from the end of the resin part 8 disposed at the end of the support pin 3. Since the semiconductor wafer 100 is not placed, the incident light is not reflected. Thus, no light is incident on the light-receiving optical fiber 61 connected to the light-receiving sensor 6 (see FIG. 2). Consequently, no light is delivered to the light-receiving sensor 6. When no light is delivered to the light-receiving sensor 6 from any one of the light-receiving optical fibers 61 included in all the support pins 3, the light-receiving sensor 6 does not output a detection signal. When the controller 10 (see FIG. 1) does not obtain the detection signal from the light-receiving sensor 6, the controller 10 determines the absence of the semiconductor wafer 100.

As illustrated in FIG. 11, the light incident from the light source 5 (see FIG. 2) is emitted, through the light-emitting optical fiber 51, from the end of the resin part 8 disposed at the end of the support pin 3. Since the semiconductor wafer 100 is placed, the light reflected from the semiconductor wafer 100 is delivered to the light-receiving sensor 6 (see FIG. 2) through the light-receiving optical fiber 61 in the resin part 8. When light is delivered to the light-receiving sensor 6 from all the light-receiving optical fibers 61 included in all the support pins 3, the light-receiving sensor 6 outputs a detection signal. When obtaining the detection signal from the light-receiving sensor 6, the controller 10 (see FIG. 1) determines the presence of the semiconductor wafer 100.

Since not only the light-emitting optical fiber 51 but also the light-receiving optical fiber 61 is disposed in the periphery of the support pin 3, the structure of the support pin 3 is simplified in Embodiment 2, in addition to the advantages of Embodiment 1. This facilitates maintenance work including replacement of the resin part 8, the light-emitting optical fiber 51, or the light-receiving optical fiber 61.

### Embodiment 3

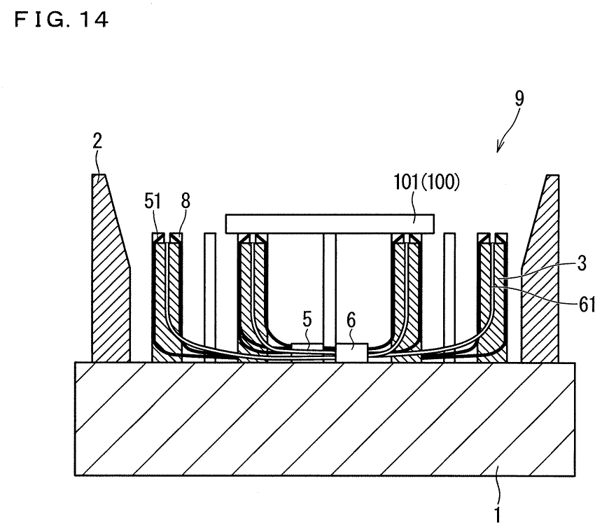

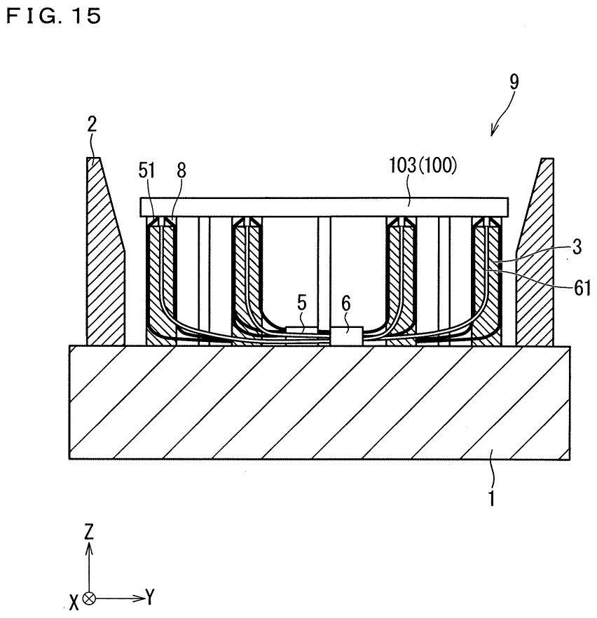

Next, Embodiment 3 will be described. FIG. 13 is a top view of the wafer detection unit 9 according to Embodiment 3. FIG. 14 is a cross-sectional view where a semiconductor wafer 101 whose φ=6 is placed on the wafer detection unit 9 according to Embodiment 3. FIG. 15 is a cross-sectional view where a semiconductor wafer 103 whose φ=12 is placed on the wafer detection unit 9 according to Embodiment 3. FIGS. 14 and 15 are cross-sectional views taken along the line B-B of FIG. 13. In Embodiment 3, the same reference numerals are assigned to the same constituent elements described in Embodiments 1 and 2, and the description thereof will be omitted.

As illustrated in FIGS. 13 to 15, the plurality of support pins 3 are disposed at positions corresponding to the periphery of each of the semiconductor wafers 100, 102, and 103 with different diameters to support the semiconductor wafers 100, 102, and 103 in Embodiment 3, unlike Embodiments 1 and 2. FIGS. 13 to 15 illustrate the wafer detection unit 9 with the structure of the support pin 3 and the resin part 8 in FIG. 3 or 4.

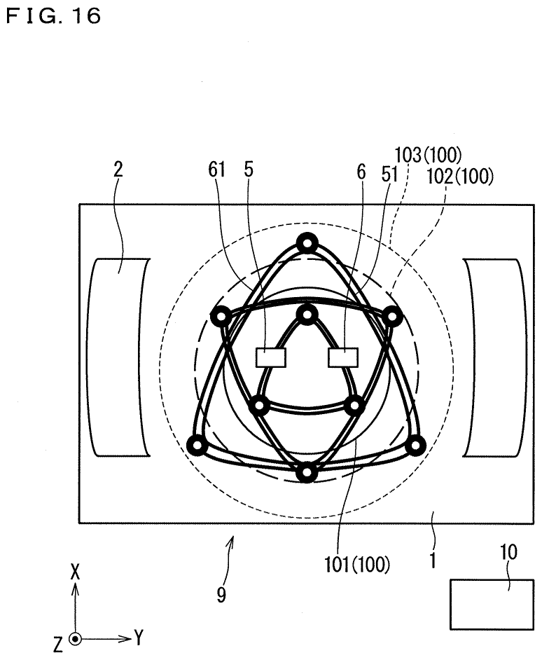

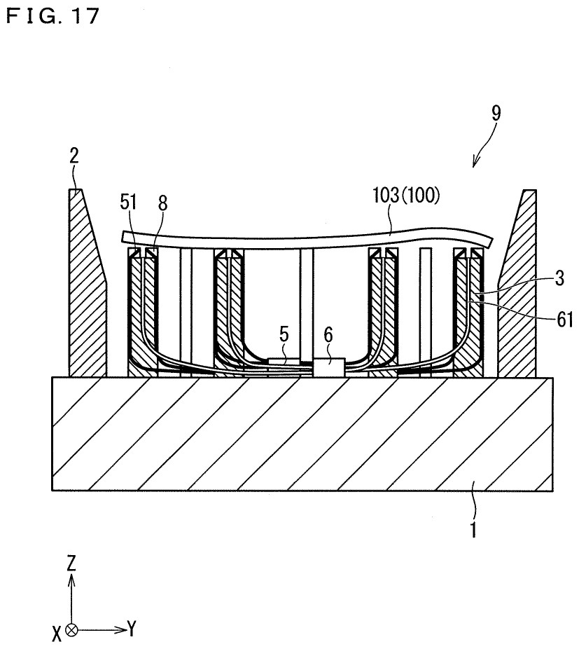

Next, operations of the wafer detection unit 9 will be described. FIG. 16 is a top view where the semiconductor wafers 101, 102, and 103 with different diameters are placed on the wafer detection unit 9 according to Embodiment 3. FIG. 17 is a cross-sectional view of the wafer detection unit 9 on which the semiconductor wafer 103 with a flatness defect is placed in Embodiment 3.

As illustrated in FIG. 16, assuming that the minimum diameter of the semiconductor wafers 100 is 6 inches, a middle diameter thereof is 8 inches, and the maximum diameter thereof is 12 inches, at least three support pins 3 are disposed at positions corresponding to the periphery of the semiconductor wafer 101 of 6 inches. Similarly, at least three support pins 3 are disposed at positions corresponding to the periphery of the semiconductor wafer 102 of 8 inches, and at least three support pins 3 are disposed at positions corresponding to the periphery of the semiconductor wafer 103 of 12 inches. A total of nine support pins 3 are disposed in Embodiment 3. The nine support pins 3 can support the plurality of semiconductor wafers 101, 102, and 103 with the different diameters.

As illustrated in FIG. 17, disposing the plurality of support pins 3 at positions corresponding to the periphery of each of the semiconductor wafers 101, 102, and 103 with the different diameters enables the controller 10 to detect the semiconductor wafer 103 with poor flatness from a detection distribution or a light intensity distribution of detection signals. The detection signals have been detected by the light-receiving sensor 6 based on the light delivered from the light-receiving optical fibers 61 included in the plurality of support pins 3.

Since the plurality of support pins 3 are disposed at the positions corresponding to the periphery of each of the semiconductor wafers 101, 102, and 103 with the different diameters as described above, the nine support pins 3 can support the plurality of semiconductor wafers 101, 102, and 103 with the different diameters. Consequently, the wafer detection unit 9 does not need a dedicated fixture that has been necessary for each of the semiconductor wafers 101, 102, and 103 in conventional structures.

Embodiments can be freely combined, or appropriately modified and omitted.

A summary of various aspects of the present disclosure will be hereinafter described as Appendixes.

### [Appendix 1]

A wafer detection unit, comprising:
a base;
a plurality of support pins that are erect on the base and can support at least one semiconductor wafer;
a resin part disposed at an end of each of the support pins such that the resin part can be in contact with the semiconductor wafer, the resin part including a through hole in a center portion;
a light-emitting optical fiber disposed in a periphery of each of the support pins and inside the resin part, the light-emitting optical fiber having one end being exposed from a side in which the through holes of the resin parts face the semiconductor wafer;
a light source connected to an other end of each of the light-emitting optical fibers;
a light-receiving optical fiber disposed in a center portion of each of the support pins, the light-receiving optical fiber having one end facing a corresponding one of the through holes of the resin parts;
a light-receiving sensor connected to an other end of each of the light-receiving optical fibers; and
a controller that determines a presence or absence of the semiconductor wafer, based on a detection signal obtained from the light-receiving sensor,
wherein when the semiconductor wafer is placed on the plurality of support pins through the resin parts, outgoing light emitted from the light source is emitted from the light-emitting optical fibers toward the semiconductor wafer, the outgoing light is reflected from the semiconductor wafer, and the reflected light from the semiconductor wafer is transmitted from the through holes of the resin parts to the light-receiving sensor through the light-receiving optical fibers, and
the controller determines the presence of the semiconductor wafer when obtaining the detection signal from the light-receiving sensor, and determines the absence of the semiconductor wafer when the controller does not obtain the detection signal.

### [Appendix 2]

The wafer detection unit according to appendix 1,
wherein the plurality of support pins comprises at least three support pins disposed at positions corresponding to a periphery of the semiconductor wafer.

### [Appendix 3]

The wafer detection unit according to appendix 2,
wherein the plurality of support pins further comprises one support pin disposed at a position corresponding to a center portion of the semiconductor wafer.

### [Appendix 4]

The wafer detection unit according to any one of appendixes 1 to 3,
wherein the controller includes a table including intensity data on the reflected light which differs for each material of a substrate included in the semiconductor wafer, and
the controller determines a type of the semiconductor wafer based on the table.

### [Appendix 5]

A wafer detection unit, comprising:
a base;
a plurality of support pins that are erect on the base and can support at least one semiconductor wafer;
a resin part disposed at an end of each of the support pins such that the resin part can be in contact with the semiconductor wafer, the resin part including a through hole in a center portion, the through hole having an inverted conical shape whose diameter is increased from the support pin toward the semiconductor wafer;
a light-emitting optical fiber disposed in a periphery of each of the support pins and inside the resin part, the light-emitting optical fiber having one end being exposed from a sloping surface forming the through hole of the resin part, the through hole having the inverted conical shape;
a light source connected to an other end of each of the light-emitting optical fibers;
a light-receiving optical fiber disposed in the periphery of each of the support pins and inside the resin part, the light-receiving optical fiber having one end being exposed from a portion facing a corresponding one of the light-emitting optical fibers in the sloping surface forming the through hole of the resin part, the through hole having the inverted conical shape;
a light-receiving sensor connected to an other end of each of the light-receiving optical fibers; and
a controller that determines a presence or absence of the semiconductor wafer, based on a detection signal obtained from the light-receiving sensor,
wherein when the semiconductor wafer is placed on the plurality of support pins through the resin parts, outgoing light emitted from the light source is emitted from the light-emitting optical fibers toward the semiconductor wafer, the outgoing light is reflected from the semiconductor wafer, and the reflected light from the semiconductor wafer is transmitted from the through holes of the resin parts to the light-receiving sensor through the light-receiving optical fibers, and
the controller determines the presence of the semiconductor wafer when obtaining the detection signal from the light-receiving sensor, and determines the absence of the semiconductor wafer when the controller does not obtain the detection signal.

### [Appendix 6]

A wafer detection unit, comprising:
a base;
a plurality of support pins that are erect on the base and can support at least one semiconductor wafer;
a resin part disposed at an end of each of the support pins such that the resin part can be in contact with the semiconductor wafer, the resin part including a through hole in a center portion;
a light-emitting optical fiber disposed in a periphery of each of the support pins and inside the resin part, the light-emitting optical fiber having one end being exposed from a side in which the through holes of the resin parts face the semiconductor wafer;
a light source connected to an other end of each of the light-emitting optical fibers;
a light-receiving optical fiber disposed in the periphery of each of the support pins and inside the resin part, the light-receiving optical fiber having one end being exposed from a portion facing a corresponding one of the light-emitting optical fibers on the side in which the through holes of the resin parts face the semiconductor wafer;
a light-receiving sensor connected to an other end of each of the light-receiving optical fibers; and
a controller that determines a presence or absence of the semiconductor wafer, based on a detection signal obtained from the light-receiving sensor,
wherein when the semiconductor wafer is placed on the plurality of support pins through the resin parts, outgoing light emitted from the light source is emitted from the light-emitting optical fibers toward the semiconductor wafer, the outgoing light is reflected from the semiconductor wafer, and the reflected light from the semiconductor wafer is transmitted from the through holes of the resin parts to the light-receiving sensor through the light-receiving optical fibers, and
the controller determines the presence of the semiconductor wafer when obtaining the detection signal from the light-receiving sensor, and determines the absence of the semiconductor wafer when the controller does not obtain the detection signal.

### [Appendix 7]

The wafer detection unit according to any one of appendixes 1 to 6,
wherein the at least one semiconductor wafer comprises a plurality of semiconductor wafers, and the plurality of support pins are disposed at positions corresponding to a periphery of each of the plurality of semiconductor wafers with different diameters.

While the disclosure has been shown and described in detail, the foregoing description is in all aspects illustrative and not restrictive. It is therefore understood that numerous modifications and variations can be devised.

What is claimed is:

1. A wafer detection unit, comprising:
a base;
a plurality of support pins that are erect on the base and can support at least one semiconductor wafer;
a resin part disposed at an end of each of the support pins such that the resin part can be in contact with the semiconductor wafer, the resin part including a through hole in a center portion;
a light-emitting optical fiber disposed in a periphery of each of the support pins and inside the resin part, the light-emitting optical fiber having one end being exposed from a side in which the through holes of the resin parts face the semiconductor wafer;
a light source connected to an other end of each of the light-emitting optical fibers;
a light-receiving optical fiber disposed in a center portion of each of the support pins, the light-receiving optical fiber having one end facing a corresponding one of the through holes of the resin parts;
a light-receiving sensor connected to an other end of each of the light-receiving optical fibers; and
a controller that determines a presence or absence of the semiconductor wafer, based on a detection signal obtained from the light-receiving sensor,
wherein when the semiconductor wafer is placed on the plurality of support pins through the resin parts, outgoing light emitted from the light source is emitted from the light-emitting optical fibers toward the semiconductor wafer, the outgoing light is reflected from the semiconductor wafer, and the reflected light from the semiconductor wafer is transmitted from the through holes of the resin parts to the light-receiving sensor through the light-receiving optical fibers, and
the controller determines the presence of the semiconductor wafer when obtaining the detection signal from the light-receiving sensor, and determines the absence of the semiconductor wafer when the controller does not obtain the detection signal.

2. The wafer detection unit according to claim 1,
wherein the plurality of support pins comprises at least three support pins disposed at positions corresponding to a periphery of the semiconductor wafer.

3. The wafer detection unit according to claim 2,
wherein the plurality of support pins further comprises one support pin disposed at a position corresponding to a center portion of the semiconductor wafer.

4. The wafer detection unit according to claim 1,
wherein the controller includes a table including intensity data on the reflected light which differs for each material of a substrate included in the semiconductor wafer, and
the controller determines a type of the semiconductor wafer based on the table.

5. The wafer detection unit according to claim 2,
wherein the controller includes a table including intensity data on the reflected light which differs for each material of a substrate included in the semiconductor wafer, and
the controller determines a type of the semiconductor wafer based on the table.

6. The wafer detection unit according to claim 3,
wherein the controller includes a table including intensity data on the reflected light which differs for each material of a substrate included in the semiconductor wafer, and
the controller determines a type of the semiconductor wafer based on the table.

7. A wafer detection unit, comprising:
a base;
a plurality of support pins that are erect on the base and can support at least one semiconductor wafer;
a resin part disposed at an end of each of the support pins such that the resin part can be in contact with the semiconductor wafer, the resin part including a through hole in a center portion, the through hole having an inverted conical shape whose diameter is increased from the support pin toward the semiconductor wafer;
a light-emitting optical fiber disposed in a periphery of each of the support pins and inside the resin part, the light-emitting optical fiber having one end being exposed from a sloping surface forming the through hole of the resin part, the through hole having the inverted conical shape;
a light source connected to an other end of each of the light-emitting optical fibers;
a light-receiving optical fiber disposed in the periphery of each of the support pins and inside the resin part, the light-receiving optical fiber having one end being exposed from a portion facing a corresponding one of the light-emitting optical fibers in the sloping surface forming the through hole of the resin part, the through hole having the inverted conical shape;
a light-receiving sensor connected to an other end of each of the light-receiving optical fibers; and
a controller that determines a presence or absence of the semiconductor wafer, based on a detection signal obtained from the light-receiving sensor,
wherein when the semiconductor wafer is placed on the plurality of support pins through the resin parts, outgoing light emitted from the light source is emitted from the light-emitting optical fibers toward the semiconductor wafer, the outgoing light is reflected from the semiconductor wafer, and the reflected light from the semiconductor wafer is transmitted from the through holes of the resin parts to the light-receiving sensor through the light-receiving optical fibers, and
the controller determines the presence of the semiconductor wafer when obtaining the detection signal from the light-receiving sensor, and determines the absence of the semiconductor wafer when the controller does not obtain the detection signal.

8. A wafer detection unit, comprising:
a base;
a plurality of support pins that are erect on the base and can support at least one semiconductor wafer;
a resin part disposed at an end of each of the support pins such that the resin part can be in contact with the semiconductor wafer, the resin part including a through hole in a center portion;
a light-emitting optical fiber disposed in a periphery of each of the support pins and inside the resin part, the light-emitting optical fiber having one end being exposed from a side in which the through holes of the resin parts face the semiconductor wafer;
a light source connected to an other end of each of the light-emitting optical fibers;
a light-receiving optical fiber disposed in the periphery of each of the support pins and inside the resin part, the light-receiving optical fiber having one end being exposed from a portion facing a corresponding one of the light-emitting optical fibers on the side in which the through holes of the resin parts face the semiconductor wafer;
a light-receiving sensor connected to an other end of each of the light-receiving optical fibers; and
a controller that determines a presence or absence of the semiconductor wafer, based on a detection signal obtained from the light-receiving sensor,
wherein when the semiconductor wafer is placed on the plurality of support pins through the resin parts, outgoing light emitted from the light source is emitted from the light-emitting optical fibers toward the semiconductor wafer, the outgoing light is reflected from the semiconductor wafer, and the reflected light from the semiconductor wafer is transmitted from the through holes of the resin parts to the light-receiving sensor through the light-receiving optical fibers, and
the controller determines the presence of the semiconductor wafer when obtaining the detection signal from the light-receiving sensor, and determines the absence of the semiconductor wafer when the controller does not obtain the detection signal.

9. The wafer detection unit according to claim 1,
wherein the at least one semiconductor wafer comprises a plurality of semiconductor wafers, and the plurality of support pins are disposed at positions corresponding to a periphery of each of the plurality of semiconductor wafers with different diameters.

10. The wafer detection unit according to claim 2,
wherein the at least one semiconductor wafer comprises a plurality of semiconductor wafers, and the plurality of support pins are disposed at positions corresponding to a periphery of each of the plurality of semiconductor wafers with different diameters.

11. The wafer detection unit according to claim 3,
wherein the at least one semiconductor wafer comprises a plurality of semiconductor wafers, and the plurality of support pins are disposed at positions corresponding to a periphery of each of the plurality of semiconductor wafers with different diameters.

12. The wafer detection unit according to claim 4,
wherein the at least one semiconductor wafer comprises a plurality of semiconductor wafers, and the plurality of support pins are disposed at positions corresponding to a periphery of each of the plurality of semiconductor wafers with different diameters.

13. The wafer detection unit according to claim 5,
wherein the at least one semiconductor wafer comprises a plurality of semiconductor wafers, and the plurality of support pins are disposed at positions corresponding to a periphery of each of the plurality of semiconductor wafers with different diameters.

14. The wafer detection unit according to claim 6,
wherein the at least one semiconductor wafer comprises a plurality of semiconductor wafers, and the plurality of support pins are disposed at positions corresponding to a periphery of each of the plurality of semiconductor wafers with different diameters.

15. The wafer detection unit according to claim 7,
wherein the at least one semiconductor wafer comprises a plurality of semiconductor wafers, and the plurality of support pins are disposed at positions corresponding to a periphery of each of the plurality of semiconductor wafers with different diameters.

16. The wafer detection unit according to claim 8,
wherein the at least one semiconductor wafer comprises a plurality of semiconductor wafers, and the plurality of support pins are disposed at positions corresponding to a periphery of each of the plurality of semiconductor wafers with different diameters.
